(19) United States
(12) Patent Application Publication
(10) Pub. No.: US 2022/0352418 A1
(43) Pub. Date: Nov. 3, 2022

(54) SEMICONDUCTOR LIGHT EMITTING ELEMENT AND ELECTRONIC APPARATUS

(71) Applicants: SONY GROUP CORPORATION, TOKYO (JP); SONY SEMICONDUCTOR SOLUTIONS CORPORATION, KANAGAWA (JP)

(72) Inventors: HIDEKAZU AOYAGI, KUMAMOTO (JP); HIROYUKI OKUYAMA, TOKYO (JP)

(21) Appl. No.: 17/755,629

(22) PCT Filed: Nov. 10, 2020
(86) PCT No.: PCT/JP2020/041889

§ 371 Date: May 4, 2022

(30) Foreign Application Priority Data
Nov. 12, 2019 (JP) 2019-204911

(51) Int. Cl. H01L 33/14; H01L 33/42

(52) U.S. Cl. CPC H01L 33/14; H01L 33/42

(57) ABSTRACT

Provided is a semiconductor light emitting element including a semiconductor stacked structure having a projecting portion from which light is emitted, an insulating layer provided on a side face of the projecting portion and a bottom face on a periphery of the projecting portion, a transparent electrode provided on a top face of the projecting portion and on at least part of a front surface of the insulating layer, and an electrode covering the bottom face on the periphery of the projecting portion and covering at least part of the transparent electrode provided on the front surface of the insulating layer.

### TECHNICAL FIELD

The present disclosure relates to a semiconductor light emitting element and an electronic apparatus including the same.

### BACKGROUND ART

A semiconductor light emitting element in the past may use a transparent electrode in order to prevent interception of light emitted from main light emitting portions and enhance light extraction efficiency, in some cases. An opaque electrode for injecting a current needs to be formed on a front face of the transparent electrode, thereby causing reduction in light extraction efficiency. In order to avoid this reduction in light extraction efficiency, PTL 1 and PTL 2 propose techniques that provide an external connection electrode in a non-light emission portion serving as a light extracting face, to prevent light from being blocked by the opaque external connection electrode.

### CITATION LIST

### Patent Literature

[PTL 1]

WO 2016/125344A
[PTL 2]

JP 2012-156555A

### SUMMARY

### Technical Problem

In a case in which there are present a large number of light extraction faces due to irregularities formed as a result of a current narrowing structure, however, a radiation light from a light emitting layer is radiated in an unintended direction from the large number of existing light extraction faces. Thus, the far field pattern (FFP) may deviate from the Lambertian distribution.

An object of the present disclosure is to provide a semiconductor light emitting element capable of obtaining the Lambertian distribution or a far field pattern close thereto and an electronic apparatus including the same.

### Solution to Problem

In order to solve the above problem, according to the present disclosure, there is provided a semiconductor light emitting element including a semiconductor stacked structure having a projecting portion from which light is emitted, an insulating layer provided on a side face of the projecting portion and a bottom face on a periphery of the projecting portion, a transparent electrode provided on a top face of the projecting portion and on at least part of a front surface of the insulating layer, and an electrode covering the bottom face on the periphery of the projecting portion and covering at least part of the transparent electrode provided on the front surface of the insulating layer.

### BRIEF DESCRIPTION OF DRAWINGS

FIG. 1 is a cross-sectional view illustrating a configuration example of a compound semiconductor light emitting element according to an embodiment of the present disclosure.

FIG. 2A is a diagram illustrating an example of a far field pattern of the compound semiconductor light emitting element according to the embodiment of the present disclosure. FIG. 2B is a cross-sectional view illustrating an example of a path of radiation light of the compound semiconductor light emitting element according to the embodiment of the present disclosure.

FIG. 3A is a diagram illustrating an example of a far field pattern of a conventional compound semiconductor light emitting element. FIG. 3B is a cross-sectional view illustrating an example of a path of radiation light of the conventional compound semiconductor light emitting element.

FIG. 4 is a cross-sectional view illustrating a configuration example of a compound semiconductor light emitting element according to a modification example 1.

FIG. 5A is a cross-sectional view illustrating an example of a current distribution of the compound semiconductor light emitting element according to the modification example 1. FIG. 5B is a cross-sectional view illustrating an example of a current distribution of the conventional compound semiconductor light emitting element.

FIG. 6 is a cross-sectional view illustrating a configuration example of a compound semiconductor light emitting element according to a modification example 2.

FIG. 7 is a cross-sectional view illustrating a configuration example of a compound semiconductor light emitting element according to a modification example 3.

FIG. 8 is a cross-sectional view illustrating a configuration example of a compound semiconductor light emitting element according to modification examples 4 and 5.

### DESCRIPTION OF EMBODIMENT

An embodiment of the present disclosure will be described in the following order. Note that components having the same function are denoted by the same reference signs throughout the drawings for describing the embodiment below.

1. Configuration of Light Emitting Element

2. Advantageous Effect

3. Modification Examples

4. Application Examples

### 1. CONFIGURATION OF LIGHT EMITTING ELEMENT

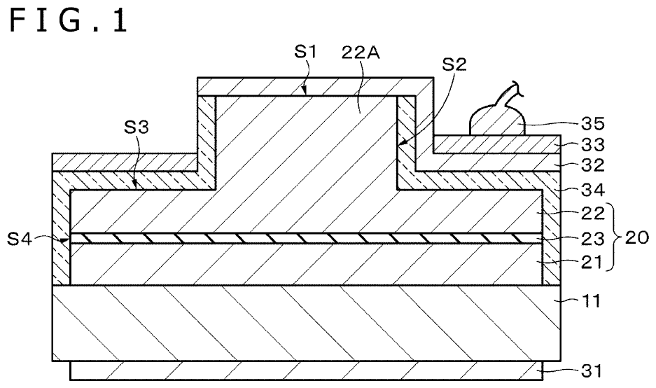

FIG. 1 is a cross-sectional view illustrating a configuration example of a compound semiconductor light emitting element (hereinafter, referred to simply as a “light emitting element”) according to an embodiment of the present disclosure. The light emitting element includes a substrate 11, a compound semiconductor stacked structure (hereinafter referred to simply as a “stacked structure”) 20, a first electrode 31, a second electrode 32, a third electrode 33, and an insulating layer 34.

(Substrate)

The substrate 11 supports the stacked structure 20. The substrate 11 has a first main face provided on a side of the stacked structure 20, and a second main face provided on a side opposite to the first main face. The substrate 11 is, for example, a GaAs substrate, a GaN substrate, an SiC substrate, an alumina substrate, a sapphire substrate, a ZnS substrate, a ZnO substrate, an AlN substrate, an LiMgO substrate, an LiGaO₂ substrate, an MgAl₂O₄ substrate, an InP substrate, an Si substrate, a Ge substrate, a GaP substrate, an AlP substrate, an InN substrate, an AlGaInN substrate, an AlGaN substrate, an AlInN substrate, a GaInN substrate, an AlGaInP substrate, an AlGaP substrate, an AlInP substrate, or a GaInP substrate. The substrate 11 may have a base layer, a buffer layer, or the like provided on the first main face.

(Stacked Structure)

The stacked structure 20 is provided on the first main face of the substrate 11. The stacked structure 20 has a first main face provided on a side opposite to the substrate 11 side, and a second main face provided on the substrate 11 side. The stacked structure 20 has a projecting portion 22A on the first main face thereof. Light is emitted from a top face S1 of the projecting portion 22A. The projecting 22A portion is provided at a position apart from an upper end of a side face S4 of the stacked structure 20, and a bottom face S3 is provided on the entire periphery of the projecting portion 22A. The bottom face S3 has a planar shape, for example.

In the present specification, the periphery of the projecting portion 22A means a region from a lower end of a side face S2 of the projecting portion 22A to the upper end of the side face S4 of the stacked structure 20. In addition, in the present specification, “up” refers to a direction away from the first main face of the substrate 11 in a direction orthogonal to the first main face of the substrate 11, while “down” refers to a direction approaching the first main face of the substrate 11 in the direction orthogonal to the first main face of the substrate 11.

The stacked structure 20 includes a plurality of compound semiconductor layers stacked on top of another. Specifically, the stacked structure 20 includes a first compound semiconductor layer 21, a second compound semiconductor layer 22, and a light emitting layer 23. The light emitting layer 23 is provided between the first compound semiconductor layer 21 and the second compound semiconductor layer 22. Note that a configuration of the stacked structure 20 is not limited to this and may have a stacked structure other than those described above.

The first compound semiconductor layer 21 has a first main face provided on a side opposite to the light emitting layer 23 side, and a second main face provided on the light emitting layer 23 side. The first compound semiconductor layer 21 has the projecting portion 22A described above on the first main face.

The first compound semiconductor layer 21 has a first conductive type, and the second compound semiconductor layer 22 has a second conductive type opposite to the first conductive type. Specifically, the first compound semiconductor layer 21 has an n type, and the second compound semiconductor layer 22 has a p type.

The first compound semiconductor layer 21 and the second compound semiconductor layer 22 include compound semiconductors. Examples of the compound semiconductors include a GaN-based compound semiconductor (including an AlGaN mixed crystal, an AlInGaN mixed crystal, or an InGaN mixed crystal), an InN-based compound semiconductor, an InP-based compound semiconductor, an AlN-based compound semiconductor, a GaAs-based compound semiconductor, an AlGaAs-based compound semiconductor, an AlGaInP-based compound semiconductor, an AlGaInAs-based compound semiconductor, an AlAs-based compound semiconductor, a GaInAs-based compound semiconductor, a GaInAsP-based compound semiconductor, a GaP-based compound semiconductor, and a GaInP-based compound semiconductor.

Examples of n-type impurities added to the first compound semiconductor layer 21 include Silicon (Si), Selenium (Se), Germanium (Ge), Tin (Sn), Carbon (C), or Titanium (T). Examples of p-type impurities added to the second compound semiconductor layer 22 include Zinc (Zn), Magnesium (Mg), Beryllium (Be), Cadmium (Cd), Calcium (Ca), Barium (Ba), or Oxygen (0).

The light emitting layer 23 includes compound semiconductors. Examples of the compound semiconductors can include the same materials as the first compound semiconductor layer 21 and the second compound semiconductor layer 22. The light emitting layer 23 may include a single compound semiconductor layer or may have a single quantum well structure (SQW structure) or a multiple quantum well structure (MQW structure).

(First Electrode)

The first electrode 31 is provided on the second main face of the substrate 11. The first electrode 31 includes at least one type of metal (including an alloy) selected from a group including Gold (Au), Silver (Ag), Palladium (Pd), Platinum (Pt), Nickel (Ni), Aluminum (Al), Titanium (Ti), Tungsten (W), Vanadium (V), Chromium (Cr), Copper (Cu), Zinc (Zn), Tin (Sn), and Indium (In), for example.

The first electrode 31 has a single-layer configuration or a multi-layer configuration, for example. Examples of the multi-layer configuration include Ti/Au, Ti/Al, Ti/Pt/Au, Ti/Al/Au, Ni/Au, AuGe/Ni/Au, Ni/Au/Pt, Ni/Pt, Pd/Pt, Ag/Pd, or the like. Note that the leftmost layer of “/” in the multi-layer configuration is positioned closer to the light emitting layer 23 side. The same applies to the following description.

(Insulating Layer)

The insulating layer 34 is provided to cover the entire side face S2 and the bottom face S3 on the entire periphery of the projecting portion 22A as well as the entire side face S4 of the stacked structure 20. The insulating layer 34 provides a current narrowing structure on the first main face side of the stacked structure 20. In such a manner, provision of the current narrowing structure can enhance a light emission efficiency of the light emitting element.

The insulating layer 34 includes an SiOₓ-based material, an SiN_{y}-based material, an SiOₓN_{y}-based material, Ta₂O₅, ZrO2, AIN, or AI₂O₃, for example.

(Second Electrode)

The second electrode 32 is provided on the top face S1 of the projecting portion 22A and at least part of a front surface of the insulating layer 34. More specifically, the second electrode 32 covers the top face S1 of the projecting portion 22A, part of the side face S2, and part of the bottom face S3. The second electrode 32 covering the top face S1 of the projecting portion 22A is provided on the top face S1 of the projecting portion 22A. The second electrode 32 covering part of the side face S2 and part of the bottom face S3 are provided on the insulating layer 34.

The second electrode 32 is a transparent electrode. The second electrode 32 includes a transparent conductive material, for example. The transparent conductive material includes, for example, Indium Oxide, Indium Tin Oxide (ITO, including Sn-doped In₂O₃, crystal ITO, and amorphous ITO), Indium Zinc Oxide (IZO), Indium Gallium Oxide (IGO), Indium-doped Gallium Zinc Oxide (IGZO, In—GaZnO₄), IFO (F-doped In₂O₃), Tin Oxide (SnO₂), ATO (Sb-doped SnO2), FTO (F-doped SnO₂), Zinc Oxide (ZnO, including Al-doped ZnO, B-doped ZnO, and Ga-doped ZnO), Antimony Oxide, Spinel-type Oxide, or Oxide with a YbFe₂O₄ structure. Alternatively, the second electrode 32 may be a transparent conductive layer having, as a mother layer, Gallium Oxide, Titanium Oxide, Niobium Oxide, Nickel Oxide, or the like.

The second electrode 32 may include an opaque conductive material (metal). Examples of the opaque conductive material include at least one type of metal selected from a group including Palladium (Pd), Platinum (Pt), Nickel (Ni), Aluminum (Al), Titanium (Ti), Gold (Au), and Silver (Ag).

The second electrode 32 may be a single-layer configuration or a multi-layer configuration (e.g., Ti/Pt/Au).

(Third Electrode)

The third electrode 33 is a reflection layer having a light reflectivity to light having a prescribed wavelength band, such as visible light. The third electrode 33 covers the bottom face S3 on the entire periphery of the projecting portion 22A and covers at least part of the second electrode 32 provided on the front surface of the insulating layer 34. The third electrode 33 covering the bottom face S3 is provided on a front surface of the second electrode 32 and the front surface of the insulating layer 34 exposed from the second electrode 32. A shape of the third electrode 33 in plan view is a ring-like shape, for example. Although FIG. 1 illustrates a case in which the entire bottom face S3 is covered with the second electrode 32, part of the bottom face S3 may be covered with the second electrode 32. A current introducing wiring 35 is connected to the third electrode 33 over the bottom face S3.

The third electrode 33 as the reflection layer include at least one type selected from a group including Al, Ag, Au, and Cu, for example.

### 2. ADVANTAGEOUS EFFECT

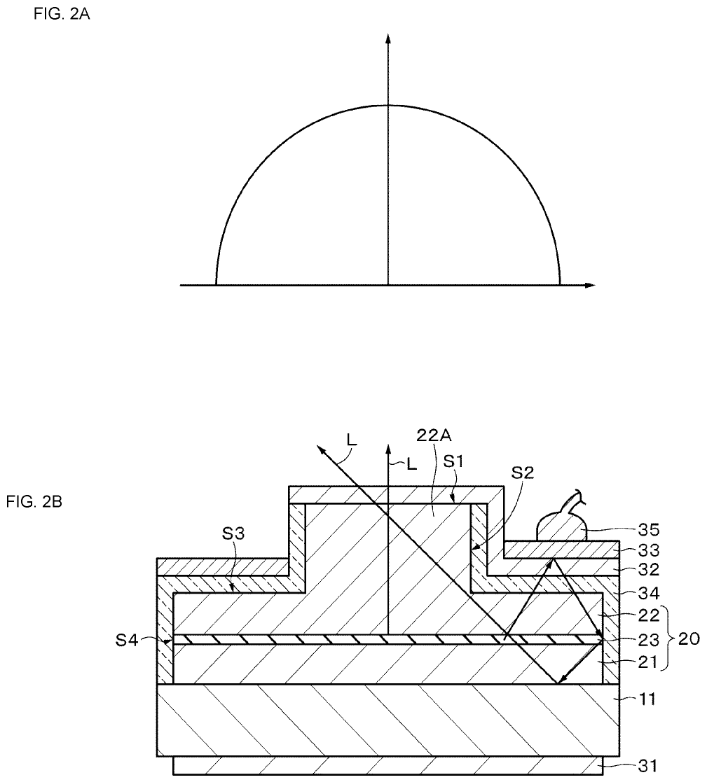

In the light emitting element according to the embodiment, when voltage is applied to the light emitting element, an electron is injected from the first compound semiconductor layer 21 into the light emitting layer 23, and conversely, a hole is injected from the second compound semiconductor layer 22 into the light emitting layer 23. As a result, the electron-hole pairs recombine and vanish in the light emitting layer 23, emitting light. Among light L having been emitted from the light emitting layer 23, light L having entered the bottom face S3 is reflected by the third electrode 33, then reflected by the side face S4 of the stacked structure 20, then reflected by an interface between the substrate 11 and the stacked structure 20, or the like, and consequently, going out from the top face S1 of the projecting portion 22A, as illustrated in FIG. 2B. Alternatively, the light L having entered the bottom face S3 is first reflected by the third electrode 33, repetitively reflected between the side face S4 of the stacked structure 20, the interface between the substrate 11 and the stacked structure 20, interfaces between the layers of the stacked structure 20, an interface between the substrate 11 and the first electrode 31, or the like, and the third electrode 33, and consequently, going out from the top face S1 of the projecting portion 22A. Accordingly, a portion from which light L is radiated can be limited to the projecting portion 22A. As a result, as illustrated in FIG. 2A, it is possible to obtain the Lambertian distribution or a far field pattern close thereto. Moreover, it is also possible to enhance light output of the light emitting element.

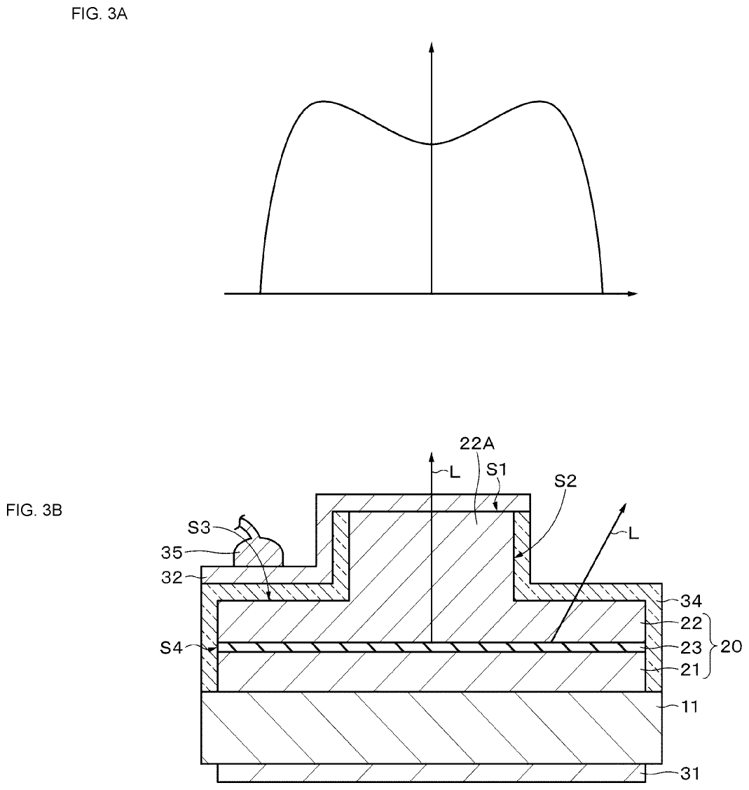

In contrast, in the conventional light emitting element, the third electrode 33 is not provided, and the light L having entered the bottom face S3 among the light L emitted from the light emitting layer 23 thus goes out from the bottom face S3, as illustrated in FIG. 3B. Accordingly, the light L is radiated in an unintended direction, and hence, as illustrated in FIG. 3A, the far field pattern deviates from the Lambertian distribution.

### 3. MODIFICATION EXAMPLES

### Modification Example 1

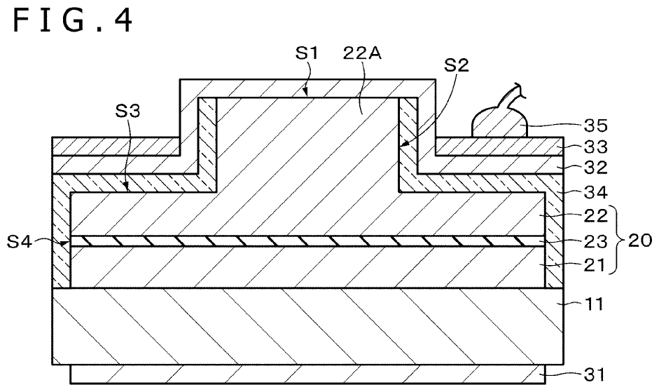

According to the embodiment described above, there has been described a case in which the second electrode 32 covers part of the side face S2 of the projecting portion 22A and part of the bottom face S3 on the periphery of the projecting portion 22A. However, as illustrated in FIG. 4, the second electrode 32 may cover the entire side face S2 of the projecting portion 22A and the bottom face S3 on the entire periphery of the projecting portion 22A.

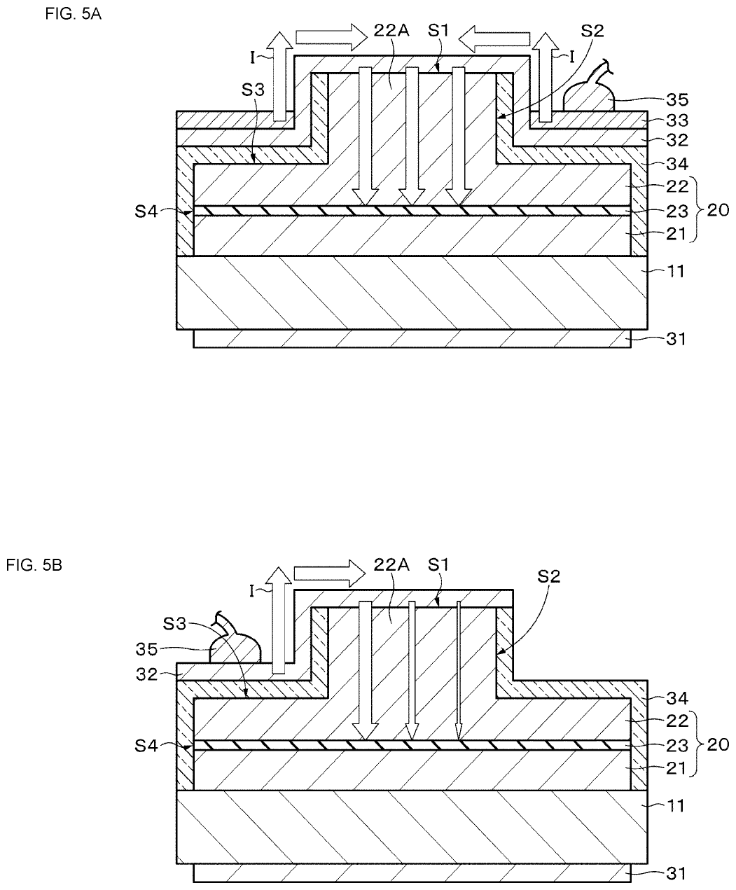

In a light emitting element according to a modification example 1 that has the above-described configuration, when voltage is applied to the light emitting element, as illustrated in FIG. 5A, a current flows from the second electrode 32 covering the entire side face S2 of the projecting portion 22A into the top face S1 of the projecting portion 22A uniformly or substantially uniformly. Thus, a potential distribution at the top face S1 becomes uniform or substantially uniform, so that light output can be enhanced more.

In contrast, in the conventional light emitting element, as illustrated in FIG. 5B, a current flows from the second electrode 32 covering the entire side face S2 of the projecting portion 22A into the top face S1 of the projecting portion 22A non-uniformly. Accordingly, the potential distribution at the top face S1 becomes non-uniform, and an effect of enhancing light output as in the light emitting element according to the modification example 1 cannot be expected.

While, in the modification example 1, there has been described a case in which the second electrode 32 covers the entire side face S2 of the projecting portion 22A, that is, a region ranging from a lower end to an upper end of the side face S2, the second electrode 32 may cover a region ranging from the lower end of the side face S2 of the projecting portion 22A to a predetermined height.

### Modification Example 2

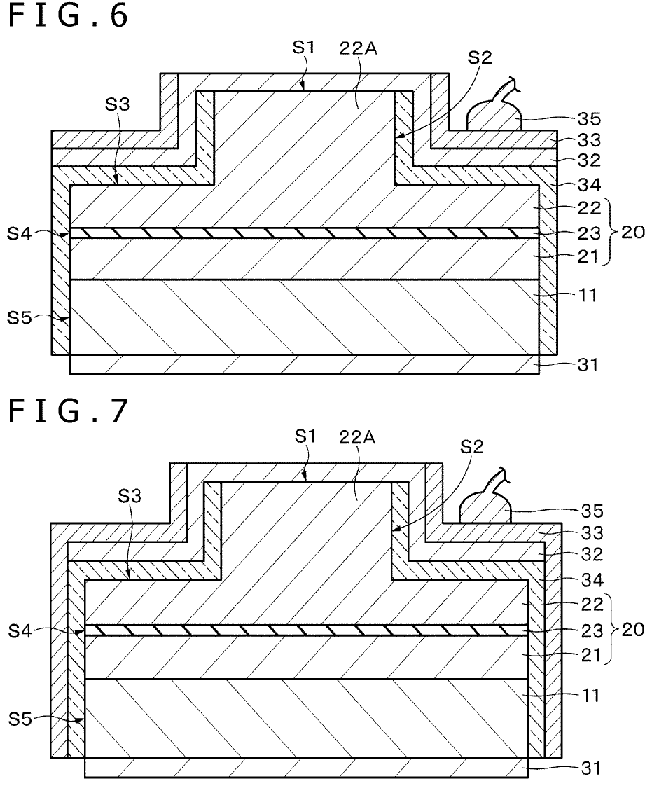

While, in the embodiment described above, there has been given a case in which the third electrode 33 covers the bottom face S3 on the entire periphery of the projecting portion 22A, the third electrode 33 may cover the bottom face S3 on the entire periphery of the projecting portion 22A and the entire side face S2 of the projecting portion 22A as illustrated in FIG. 6. In this case, light having entered the side face S2 of the projecting portion 22A can be reflected by the third electrode 33. Hence, it is possible to obtain the Lambertian distribution or a far field pattern much closer to the Lambertian distribution. In addition, it is also possible to further enhance light output of the light emitting element.

While, in the modification example 2, there has been given a case in which the third electrode 33 covers the entire side face S2 of the projecting portion 22A, the third electrode 33 may cover part of the side face S2 of the projecting portion 22A. For example, the third electrode 33 may cover a region ranging from the lower end of the side face S2 of the projecting portion 22A to a predetermined height.

### Modification Example 3

The third electrode 33 may cover the bottom face S3 on the entire periphery of the projecting portion 22A and the entire side face S4 of the stacked structure 20. In this case, light having entered the side face S4 of the stacked structure 20 can be reflected by the third electrode 33. Hence, light output of the light emitting element can be enhanced more.

While, in the modification example 3, there has been given a case in which the third electrode 33 covers the entire side face S4 of the stacked structure 20, the third electrode 33 may cover part of the side face S4 of the stacked structure 20. For example, the third electrode 33 may cover a region ranging from the upper end of the side face S4 of the stacked structure 20 to a predetermined height.

### Modification Example 4

As illustrated in FIG. 7, while the insulating layer 34 covers an entire side face S5 of the substrate 11, the third electrode 33 may cover the bottom face S3 on the entire periphery of the projecting portion 22A, the entire side face S4 of the stacked structure 20, and the entire side face S5 of the substrate 11. In this case, the light having entered the side face S4 of the stacked structure 20 and the side face S5 of the substrate 11 can be reflected by the third electrode 33. Hence, light output of the light emitting element can be enhanced more. Note that, although FIG. 7 illustrates a case in which the third electrode 33 covers the entire side face S2 of the projecting portion 22A, the third electrode 33 may not cover the entire side face S2 of the projecting portion 22A.

While, in the modification example 4, there has been given a case in which the insulating layer 34 and the third electrode 33 cover the entire side face S5 of the substrate 11, the insulating layer 34 and the third electrode 33 may cover part of the side face S5 of the substrate 11. For example, the insulating layer 34 and the third electrode 33 may cover a region ranging from an upper end of the side face S5 of the substrate 11 to a predetermined height.

### Modification Example 5

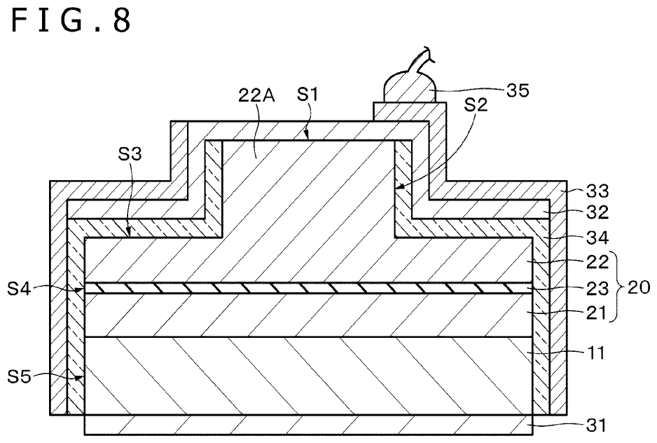

As illustrated in FIG. 8, the third electrode 33 may cover the bottom face S3 on the entire periphery of the projecting portion 22A and the entire side face S2 of the projecting portion 22A, as well as part of the top face S1 of the projecting portion 22A. The part of the top face S1 is, for example, part or all of a peripheral edge portion of the top face S1. Note that FIG. 8 illustrates an example in which the third electrode 33 covers part of the peripheral edge portion of the top face S1 as part of the top face S1. In a case in which the third electrode 33 covers the part of the top face S1 of the projecting portion 22A as described above, the current introducing wiring 35 may be connected to the third electrode 33 over the top face S1. Such a connection mode of the current introducing wiring 35 is effective in a case in which an area of the bottom face S3 is small and it is difficult to connect the current introducing wiring 35 with the third electrode 33 over the bottom face S3. Note that, although FIG. 8 illustrates a case in which the third electrode 33 covers the entire side face S4 of the stacked structure 20 and the entire side face S5 of the substrate 11, the third electrode 33 may not cover the entire side face S4 of the stacked structure 20 and the entire side face S5 of the substrate 11.

### Modification Example 6

While, in the embodiment described above, there has been given a case in which the third electrode 33 is a reflection layer having light reflectivity to light having a prescribed wavelength band, such as visible light, the third electrode 33 may be an absorbing layer having a light absorbing property to light having a prescribed wavelength band, such as visible light. In this case, light having entered the bottom face S3 can be absorbed by the third electrode 33. Accordingly, it is possible to obtain the Lambertian distribution or a far field pattern close to the Lambertian distribution. Note that, in terms of improvement in luminance, as with the embodiment described above, it is preferred that the third electrode 33 be a reflection layer having light reflectivity to light having a prescribed wavelength band, such as visible light.

The third electrode 33 as an absorbing layer includes at least one type selected from a group including Ti, Si, Mo, and a carbon material, for example. The carbon material includes at least one type of carbon black (for example, ketjen black, acetylene black, or the like), porous carbon, carbon nanofiber, fullerene, graphene, vapor-grown carbon fiber (VGCF), carbon nanotube (for example, SWCNT, MWCNT, or the like), carbon microcoil, and carbon nanohorn.

### 4. APPLICATION EXAMPLES

The light emitting element according to the embodiment and the modification examples thereof described above can be applied, for example, to a device, an apparatus, a component, or the like for receiving and transmitting an optical signal. Specifically, the light emitting element can be used for a photo-coupler, a light source for a drum-photosensitive printer, a light source for a scanner, a light source for an optical fiber, a light source for an optical disc, an optical remote controller, an optical measurement device, and the like. The number of light emitting elements to be mounted on a mounting substrate is one or plural, and the number, a kind, and mounting (arrangement), an interval, and the like of light emitting elements may be determined depending on a specification, application, a function, or the like required for a device having the light emitting element. As a device obtained by mounting the light emitting element on the mounting substrate, in addition to the above devices, e.g., there can be cited an image display device, a backlight, or an illumination device. A display device unit in a display device of a tiling form in which a plurality of display device units is arranged can also be included in a device obtained by mounting the light emitting element on the mounting substrate.

The light emitting element according to the embodiment and the modification examples thereof described above can also be applied to various types of an electronic apparatus. Specific examples of an electronic apparatus include a personal computer, a mobile device, a portable phone, a tablet computer, an imaging device, a gaming device, an industrial instrument, a robot, and the like, and an electronic apparatus is not limited to those.

The light emitting element may be any of a red light emitting element, a green light emitting element, and a blue light emitting element. As the red light emitting element, the green light emitting element, and the blue light emitting element, for example, it is possible to use a light emitting element using a nitride-based III-V compound semiconductor. As the red light emitting element, it is also possible to use a light emitting element using AlGaInP-based compound semiconductor. Further, as the light emitting element, there can be cited an ultraviolet light emitting element (including nitride-based III-V compound semiconductor) and an infrared light emitting element (including AlGaAs- or GaAs-based compound semiconductor) for an invisible region used for a motion sensor and the like.

While the above description has been given in detail regarding the embodiment of the present disclosure and the modification examples thereof, the present disclosure is not limited to the embodiment of the present disclosure and the modification examples thereof described above, and various modification based on the technical scope of the present disclosure can be made.

For example, a configuration, a method, a process, a shape, a material, a numerical value, and the like which have been cited in the above-described embodiment and the modification examples thereof are merely examples, and a configuration, a method, a process, a shape, a material, a numerical value, and the like which are different from those may be used as needed.

In addition, a configuration, a method, a process, a shape, a material, a numerical value, and the like of the above-described embodiment and the modification examples thereof can be used in combination with each other, without departing from the gist of the present disclosure.

The materials exemplified in the above-described embodiment can be used alone or in combination of two or more types, unless otherwise stated.

In addition, the present disclosure can also adopt the following configurations.
(1)

A semiconductor light emitting element including:

a semiconductor stacked structure having a projecting portion from which light is emitted;

an insulating layer provided on a side face of the projecting portion and a bottom face on a periphery of the projecting portion;

a transparent electrode provided on a top face of the projecting portion and on at least part of a front surface of the insulating layer; and

an electrode covering the bottom face on the periphery of the projecting portion and covering at least part of the transparent electrode provided on the front surface of the insulating layer.
(2)

The semiconductor light emitting element according to (1) above, in which

the transparent electrode covers an entire side face of the projecting portion and the bottom face on an entire periphery of the projecting portion.
(3)

The semiconductor light emitting element according to (1) above, in which

the transparent electrode covers part of the side face of the projecting portion and part of the periphery of the projecting portion.
(4)

The semiconductor light emitting element according to any one of (1) to (3) above, in which

the electrode covers the bottom face on an entire periphery of the projecting portion.
(5)

The semiconductor light emitting element according to any

one of (1) to (4) above, in which the electrode further covers the side face of the projecting portion.
(6)

The semiconductor light emitting element according to any one of (1) to (5) above, in which

the electrode further covers part of the top face of the projecting portion.
(7)

The semiconductor light emitting element according to (6) above, in which

a current introducing wiring is connected to the electrode on the top face of the projecting portion.
(8)

The semiconductor light emitting element according to any one of (1) to (7) above, in which

the electrode further covers a side face of the semiconductor stacked structure.
(9)

The semiconductor light emitting element according to any one of (1) to (7) above, further including:

a substrate supporting the semiconductor stacked structure, in which

the semiconductor stacked structure has the projecting portion on a main face thereof opposite to the substrate, and

the electrode covers a side face of the substrate and a side face of the semiconductor stacked structure.
(10)

The semiconductor light emitting element according to any one of (1) to (9) above, in which

the semiconductor stacked structure includes a first compound semiconductor layer, a light emitting layer, and a second compound semiconductor layer, and

the light emitting layer is provided between the first compound semiconductor layer and the second compound semiconductor layer.
(11)

The semiconductor light emitting element according to any one of (1) to (10) above, in which

the electrode has light reflectivity.
(12)
The semiconductor light emitting element according to any one of (1) to (10) above, in which

the electrode has a light absorbing property.
(13)

An electronic apparatus including:

the semiconductor light emitting element according to any one of (1) to (12).

### REFERENCE SIGNS LIST

11: Substrate

20: Stacked structure

21: First compound semiconductor layer

22: Second compound semiconductor layer

22A: Projecting portion

23: Light emitting layer

31: First electrode

32: Second electrode

33: Third electrode

34: Insulating layer

35: Current introducing wiring

S1: Top face

S2, S4, S5: Side face

S3: Bottom face

1. A semiconductor light emitting element comprising:
a semiconductor stacked structure having a projecting portion from which light is emitted;
an insulating layer provided on a side face of the projecting portion and a bottom face on a periphery of the projecting portion;
a transparent electrode provided on a top face of the projecting portion and on at least part of a front surface of the insulating layer; and
an electrode covering the bottom face on the periphery of the projecting portion and covering at least part of the transparent electrode provided on the front surface of the insulating layer.

2. The semiconductor light emitting element according to claim 1, wherein
the transparent electrode covers an entire side face of the projecting portion and the bottom face on an entire periphery of the projecting portion.

3. The semiconductor light emitting element according to claim 1, wherein
the transparent electrode covers part of the side face of the projecting portion and part of the periphery of the projecting portion.

4. The semiconductor light emitting element according to claim 1, wherein
the electrode covers the bottom face on an entire periphery of the projecting portion.

5. The semiconductor light emitting element according to claim 1, wherein
the electrode further covers the side face of the projecting portion.

6. The semiconductor light emitting element according to claim 1, wherein
the electrode further covers part of the top face of the projecting portion.

7. The semiconductor light emitting element according to claim 6, wherein
a current introducing wiring is connected to the electrode on the top face of the projecting portion.

8. The semiconductor light emitting element according to claim 1, wherein
the electrode further covers a side face of the semiconductor stacked structure.

9. The semiconductor light emitting element according to claim 1, further comprising:
a substrate supporting the semiconductor stacked structure, wherein
the semiconductor stacked structure has the projecting portion on a main face thereof opposite to the substrate, and
the electrode covers a side face of the substrate and a side face of the semiconductor stacked structure.

10. The semiconductor light emitting element according to claim 1, wherein
the semiconductor stacked structure includes a first compound semiconductor layer, a light emitting layer, and a second compound semiconductor layer, and
the light emitting layer is provided between the first compound semiconductor layer and the second compound semiconductor layer.

11. The semiconductor light emitting element according to claim 1, wherein
the electrode has light reflectivity.

12. The semiconductor light emitting element according to claim 1, wherein
the electrode has a light absorbing property.

13. An electronic apparatus comprising:
the semiconductor light emitting element according to claim 1.
